(19) United States
(12) Patent Application Publication
(10) Pub. No.: US 2012/0185201 A1
(43) Pub. Date: Jul. 19, 2012

(54) AUTOMATIC POWER SUPPLY TESTING SYSTEM AND METHOD

(75) Inventor: CHI-WEN CHEN, Tu-Cheng (TW)

(73) Assignee: HON HAI PRECISION INDUSTRY CO., LTD., Tu-Cheng (TW)

(21) Appl. No.: 13/015,516

(22) Filed: Jan. 27, 2011

(30) Foreign Application Priority Data
Jan. 17, 2011 (TW) 100101683

(51) Int. Cl. G01R 31/40

(52) U.S. Cl. 702/118

(57) ABSTRACT

An automatic power supply testing system records a preset test order of first and second power supplies with a recording module. The automatic power supply testing system controls a first control unit to connect a first connector connected to the first power supply to a simulation load to test the first power supply according to the preset test order by a determination control module and obtains a first test result. The automatic power supply testing system controls a second control unit to connect a second connector connected to the second power supply to the simulation load to test the second power supply after determining that the first test result is displayed and obtain a second test result. A display module displays the electrical stability of the first and second power supplies.

### BACKGROUND

1. Technical Field

The present disclosure relates to an automatic testing system and method for a plurality of power supplies.

2. Description of Related Art

Automatic test devices are used to test electrical stability of power supplies. However, one test device is used to test one power supply at any one time. Thus, after one power supply is finished testing, users need to connect the automatic test device to another power supply to be tested, which is time-consuming and inefficient.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a block diagram of an exemplary embodiment of an automatic power supply testing system for power supplies. The automatic power supply testing system includes a computer.

FIG. 2 is a block diagram of the computer of FIG. 1.

FIG. 3 is a flowchart of an exemplary embodiment of an automatic power supply testing method for a plurality of power supplies.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

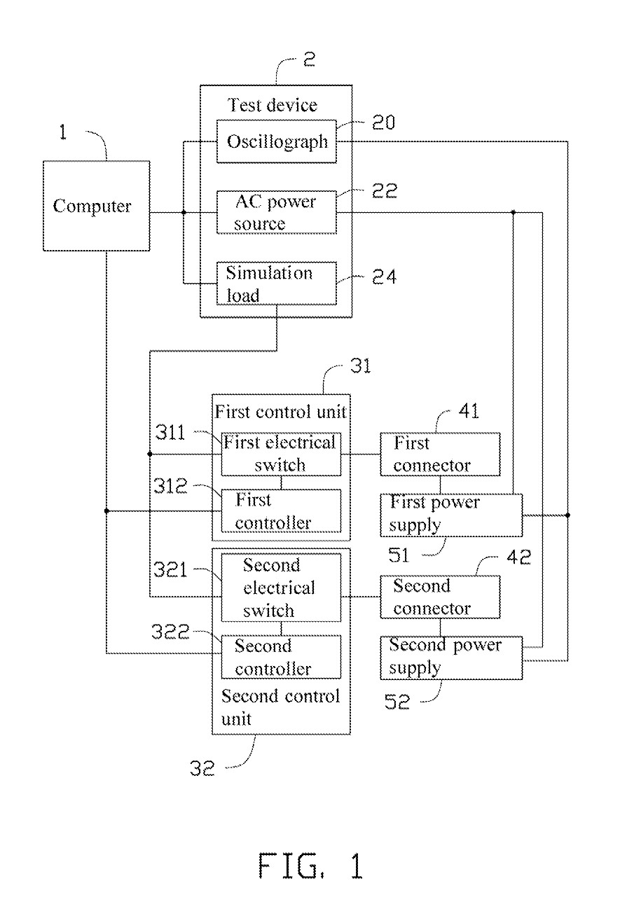

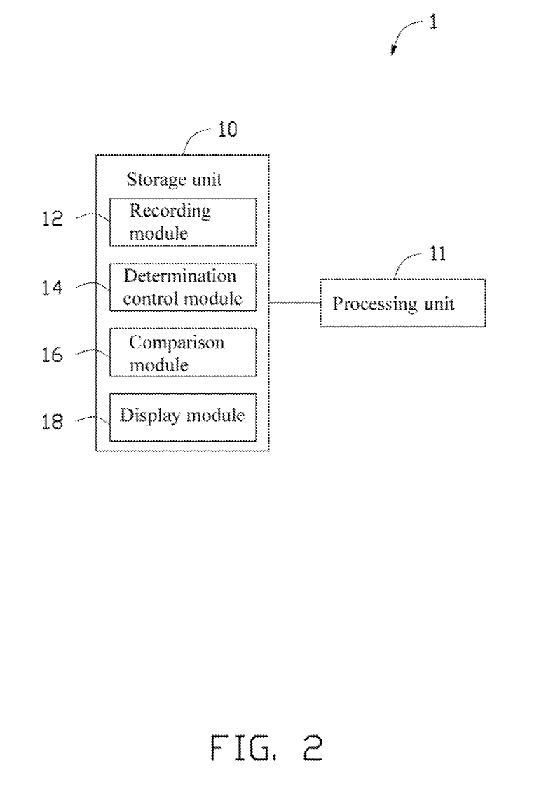

Referring to the FIGS. 1 and 2, an exemplary embodiment of an automatic power supply testing system for automatically testing the electrical stability of a plurality of power supplies, includes a computer 1, a test device 2, a first control unit 31, a second control unit 32, a first connector 41, and a second connector 42. The plurality of power supply includes a first power supply 51 and a second power supply 52, corresponding to the number of the control units and the connectors.

The test device 2 includes an oscilloscope 20, an alternating current (AC) power source 22, and a simulation load 24. The computer 1 is connected to the oscilloscope 20, the AC power source 22, and the simulation load 24, to preset reference values of the oscilloscope 20, control output of the AC power source 22, and respectively control a resistance of the simulation load 24. The first control unit 31 includes a first electrical switch 311 and a first controller 312. The second control unit 32 includes a second electrical switch 321 and a second controller 322. The first controller 312 is connected between the computer 1 and the first electrical switch 311. The second controller 322 is connected between the computer 1 and the second electrical switch 321. The first electrical switch 311 is connected between the simulation load 24 and the first connector 41. The second electrical switch 321 is connected between the simulation load 24 and the second connector 42. The first connector 41 is also connected to the first power supply 51. The second connector 42 is also connected to the second power supply 52. The AC power source 22 is used to supply AC voltage to the first and second power supplies 51 and 52. The oscilloscope 20 is connected to the first and second power supplies 51 and 52 to display waveforms of direct current (DC) voltages output by the first and second power supplies 51 and 52, and output the DC voltages to the computer 1.

In other embodiments, the number of the controller, the electrical switch, the connectors, and the power supply can be changed according to need. When the automatic power supply testing system includes a plurality of simulation loads, each simulation load is connected to the first and second electrical switches 311 and 321. The principle of work of the plurality of simulation loads is the same.

The computer 1 includes a storage unit 10 and a processing unit 11. The storage unit 10 includes a recording module 12, a determination control module 14, a comparison module 16, and a display module 18. The recording module 12, the determination control module 14, the comparison module 16, and the display module 18 may include one or more computerized instructions, which are executed by the processing unit 11.

The recording module 12 is used to record a preset test order of the first and second power supplies 51 and 52. In one embodiment, the preset test order of the first and second power supplies 51 and 52 is that the first power supply 51 is tested first, and then the second power supply 52 is tested. In other embodiments, the preset test order of the first and second can be changed according to need.

The determination control module 14 is used to transmit a first control signal to the first controller 312 according to the preset test order, to turn on the first electrical switch 311 to test the first power supply 51.

The oscilloscope 20 is used to display a waveform of a DC voltage output by a power supply in test, and output the DC voltage to the comparison module 16.

The comparison module is used to receive the DC voltage, and compares the DC voltage with a standard DC voltage, and output a test result to the display module 18.

The display module 18 is used to display the test result to ensure the electrical stability of the power supply in test.

The determination control module 14 is further used to control the first controller 312 to turn off the first electrical switch 311 after determining that the display module 18 displays the test result. In addition, the determination control module 14 output a second control signal to the second controller 322 to turn on the second electrical switch 321, to connect the simulation load 24 to the second power supply 52 through the second connector 42.

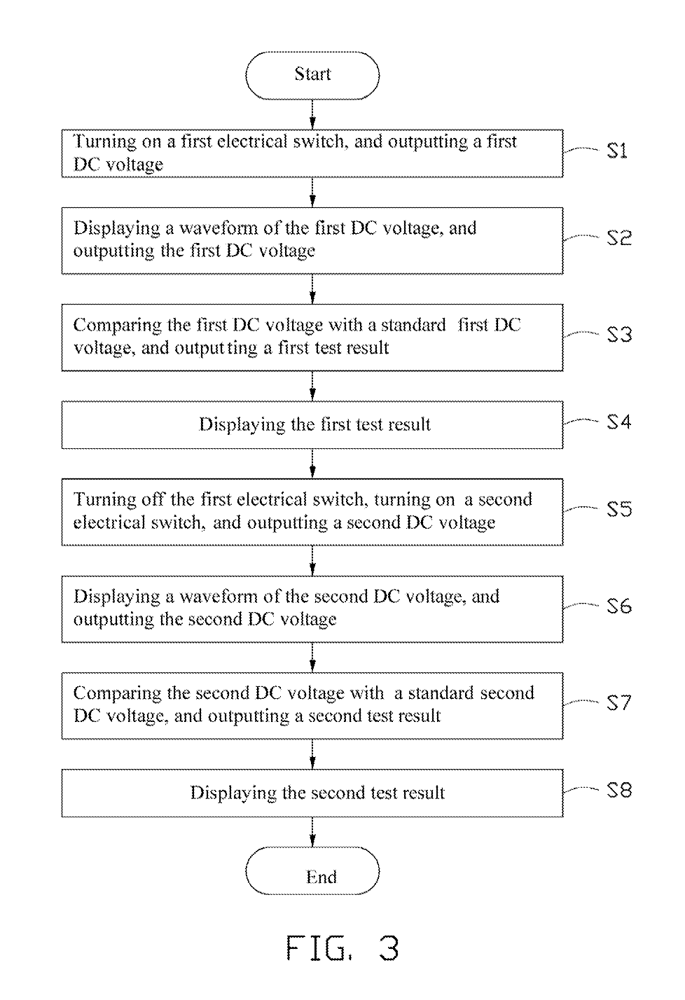

Referring to FIG. 3, an exemplary embodiment of an automatic power supply testing method is used to automatically test the electrical stability of the first and second power supplies 51 and 52. The automatic test method includes the following steps.

In step S1, the determination control module 14 transmits the first control signal to the first controller 312 to turn on the first electrical switch 311 according to the predetermined test order. Thereby, connecting the first power supply 51 to the simulation load 24 through the first electrical switch 311 and the first connector 41, resulting in the first power supply 51 outputting a first DC voltage to the oscilloscope 20.

In step S2, the oscilloscope 20 displays the waveform of the first DC voltage, and outputs the first DC voltage to the comparison module 16.

In step S3, the comparison module 16 compares the first DC voltage with a first standard DC voltage corresponding to the first power supply 51, and outputs a first test result to the display module 18.

In step S4, the display module 18 displays the first test result.

In step S5, the determination control module 14 controls the first controller 312 to turn off the first electrical switch 311 after determining that the display module 18 displays the first test result. In addition, the determination control module 14 outputs the second control signal to the second controller 322 to turn on the second electrical switch 321, thereby connecting the second power supply 52 to the simulation load 24 through the second electrical switch 321 and the second connector 42, resulting in the second power supply 52 outputting a second DC voltage to the oscilloscope 20.

In step S6, the oscilloscope 20 displays a waveform of the second DC voltage output by the second power supply 52, and outputs the second DC voltage to the comparison module 16.

In step S7, the comparison module 16 compares the second DC voltage with a second standard DC voltage corresponding to the second power supply 52, and outputs a second test result to the display module 18.

In step S8, the display module 18 displays the second test result.

The electrical stability of the first and second power supplies 51 and 52 can be ascertained by the first and second test results.

It is to be understood, however, that even though numerous characteristics and advantages of the present disclosure have been set forth in the foregoing description, together with details of the structure and function of the disclosure, the disclosure is illustrative only, and changes may be made in details, especially in matters of shape, size, and arrangement of parts within the principles of the disclosure to the full extent indicated by the broad general meaning of the terms in which the appended claims are expressed.

What is claimed is:

1. An automatic power supply testing system for automatically testing electrical stability of first and second power supplies, the automatic power supply testing system comprising:
a test device comprising an oscilloscope connected to the first and second power supplies, an alternating current (AC) power source connected to the first and second power supplies, and a simulation load;
a computer connected to the oscilloscope to preset reference values of the oscillograph, connected to the AC power source to control output of the AC power source, and connected to the simulation load to control a resistance of the simulation load;
a first connector connected to the first power supply;
a second connector connected to the second power supply;
a first control unit connected between the simulation load and the first connector, and connected to the computer; and
a second control unit connected between the simulation load and the second connector, and connected to the computer;
wherein the computer comprises:
a processing unit; and
a storage unit connected to the processing unit, and storing a plurality of modules each of which contains one or more computerized instructions being executed by the processing unit, wherein the plurality of modules comprises:
a recoding module to record a preset test order of the first and second power supplies;
a determination control module to control the first control unit to connect the first connector to the simulation load, wherein the oscilloscope receives a first direct current (DC) voltage from the first power supply, the oscilloscope is used to display a waveform of the first DC voltage, and output the first DC voltage;
a comparison module to receive the first DC voltage, compares the first DC voltage with a first standard DC voltage, and outputs a first test result;
a display module to display the first test result to obtain the electrical stability of the power supply in test, wherein the determination control module is further used to control the first control unit to disconnect the first connector from the simulation load, and control the second unit to connect the second connector to the simulation load after determining that the display module displays the first test result, the oscilloscope receives a second DC voltage from the second power supply, displays a waveform of the second DC voltage, and outputs the second DC voltage; the comparison module also further receives the second DC voltage, compares the second DC voltage with a second standard DC voltage, and outputs a second test result display by the display module.

2. The automatic power supply testing system of claim 1, wherein the first control unit comprises a first controller and a first electrical switch, the second control unit comprises a second controller and a second electrical switch, the first controller is connected between the computer and the first electrical switch, the second controller is connected between the computer and the second electrical switch, the first electrical switch is connected between the simulation load and the first connector, the second electrical switch is connected between the simulation load and the second connector, the determination control module is used to output a first control signal to the first controller to turn on the first electrical switch according to the predetermined test order, and control the first controller to turn off the first electrical switch after determining that the display module displays the first test result, and outputs a second control signal to the second controller to turn on the second electrical switch.

3. A method to automatically test electrical stability of first and second power supplies, the method comprising:
a: controlling a first control unit to connect a first connector to a simulation load according to a preset test order; wherein the simulation load receives a first direct current (DC) voltage from the first power supply;
b: displaying a waveform of the first DC voltage, and outputting the first DC voltage;
c: receiving the first DC voltage, comparing the first DC voltage with a standard first DC voltage corresponding to the first power supply, and outputting a first test result;
d: displaying the first test result;
e: controlling the first control unit to disconnect the first connector from the simulation load, and controlling a second control unit to connect the second connector to the simulation module after determining that the first test result is displayed, wherein the simulation load receives a second DC voltage from the second power supply;
f: displaying a waveform of the second DC voltage, and outputting the second DC voltage;
g: receiving the second DC voltage, comparing the second DC voltage with a standard second DC voltage corresponding to the second power supply, and outputting a second test result; and
h: displaying the second test result.

4. The method of claim 1, wherein the first control unit comprises a first controller and a first electrical switch, the second control unit comprises a second controller and a second electrical switch, the first electrical switch is connected between the simulation load and the first connector, the second electrical switch is connected between the simulation load and the second connector, in the step a, the first connector is connected to the simulation load by controlling the first controller to turn on the first electrical switch, in the step e, the first connector is disconnected from the simulation load by controlling the first controller to turn off the first electrical switch, the second connector is connected to the simulation load by controlling the second controller to turn on the second electrical switch.
